(19) United States
(12) Patent Application Publication
(10) Pub. No.: US 2024/0260367 A1
(43) Pub. Date: Aug. 1, 2024

(54) DISPLAY DEVICE

(71) Applicant: LG Display Co., Ltd., Seoul (KR)

(72) Inventor: ChiHeon KIM, Goyang-si (KR)

(73) Assignee: LG Display Co., Ltd., Seoul (KR)

(21) Appl. No.: 18/191,153

(22) Filed: Mar. 28, 2023

(30) Foreign Application Priority Data
Jan. 31, 2023 (KR) 10-2023-0012795

(51) Int. Cl. H10K 59/35

(52) U.S. Cl. CPC H10K 59/352

(57) ABSTRACT

A display device includes a substrate that has a display area in which a plurality of sub-pixels is disposed, a non-display area surrounding the display area, and at least one curved area, the display device also includes a plurality of heteromorphic sub-pixels disposed in an outer portion of the display area corresponding to the curved area. Further, the display device includes a connection part that electrically connects the plurality of sub-pixels and the plurality of heteromorphic sub-pixels, and each of the heteromorphic sub-pixels is connected to one of the plurality of sub-pixels by the connection part.

### CROSS-REFERENCE TO RELATED APPLICATION

This application claims the priority of Korean Patent Application No. 10-2023-0012795 filed on Jan. 31, 2023, which is hereby incorporated by reference in its entirety.

### BACKGROUND

### Field of the Disclosure

The present disclosure relates to a display device, and more particularly, to a display device which improves aesthetics of a curved area of a heteromorphic display device and in which a defect in the outermost portion of a display area may be easily repaired.

### Description of the Background

As the information age advances, the field of display devices for visually displaying electrical information signals has grown rapidly. Accordingly, various studies on the display devices are ongoing to improve various aspects in thin profile, light weight and low power consumption.

In the development of various technologies for implementing display devices and mass production of various products, technical enhancement is achieved on the basis of technology for implementing designs that consumers desire. One of the technologies is diversification of the shape of a display area. The display area is an area in which an image is displayed. Specifically, the display area needs to have various shapes in addition to a quadrangular shape. For example, by diversifying the shape of a display area to provide heteromorphic display devices for various purposes, such as wearable display devices, the flexibility of product designs may be secured.

The above information disclosed in this Background section is only for enhancement of understanding of the background of the described technology and therefore it may contain information that does not form prior art that is already known to a person of ordinary skill in the art.

### SUMMARY

Accordingly, the present disclosure is to provide a display device which may improve the aesthetics of a curved area and enhances display quality.

Also, the present disclosure is to provide a process-optimized display device in which heteromorphic sub-pixels for improving a step difference may be easily disposed.

Further, the present disclosure is to provide a process-optimized display device in which a defect in the outermost portion of a display area may be easily repaired.

The present disclosure is not limited to the above-mentioned, and other features, which are not mentioned above, may be clearly understood by those skilled in the art from the following descriptions.

According to an aspect of the present disclosure, a display device includes a substrate that has a display area in which a plurality of sub-pixels is disposed, a non-display area surrounding the display area, and at least one curved area. Also, the display device includes a plurality of heteromorphic sub-pixels disposed in an outer portion of the display area corresponding to the curved area. Further, the display device includes a connection part that electrically connects the plurality of sub-pixels and the plurality of heteromorphic sub-pixels. Each of the heteromorphic sub-pixels is connected to any one of the plurality of sub-pixels by the connection part.

Other detailed matters of the exemplary aspects are included in the detailed description and the drawings.

According to the present disclosure, a step difference in the curved area may be improved. Therefore, the aesthetics of the display device may be improved.

According to the present disclosure, a process of manufacturing the plurality of heteromorphic sub-pixels to have curves with different curvatures may be omitted. Therefore, the manufacturing process may be simplified and production energy may be reduced.

According to the present disclosure, a complicated process for repairing a dark spot defect may be omitted. Therefore, a defect in the outermost portion of the display area may be easily repaired and production energy may be reduced.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary aspect of the present disclosure;

FIG. 2 is an enlarged plan view of an area A shown in FIG. 1;

FIG. 3 is an enlarged plan view of an area B shown in FIG. 2;

FIG. 4 is a cross-sectional view as taken along a line C-C′ of FIG. 3;

FIG. 5A is an enlarged plan view of a display device according to another exemplary aspect of the present disclosure;

FIG. 5B is a cross-sectional view as taken along a line D-D′ of FIG. 5A;

FIG. 5C is a cross-sectional view as taken along a line E-E′ of FIG. 5A; and

FIG. 6 is an enlarged plan view of a display device according to yet another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, various aspects of the present disclosure will be described in detail with reference to accompanying drawings.

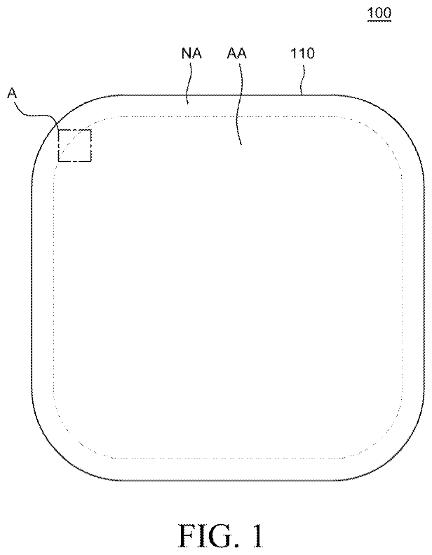

FIG. 1 is a plan view of a display device according to an exemplary aspect of the present disclosure. For the convenience of description, FIG. 1 illustrates only a substrate 110, a display area AA and a non-display area NA among various components of a display device 100.

Referring to FIG. 1, the substrate 110 of the display device 100 according to an exemplary aspect of the present disclosure includes the display area AA and the non-display area NA.

The substrate 110 is a component for supporting the other components of the display device 100 and may be made of an insulating material. For example, the substrate 110 may be made of glass or resin. Also, the substrate 110 may contain a polymer or plastic such as polyimide (PI) and may be made of a material having flexibility.

Referring to FIG. 1, the substrate 110 has at least one curved area. That is, the substrate 110 may be disposed in various shapes with a curved area. For example, the substrate 110 may have a round curved area in at least one corner, or may have a circular or polygonal shape, but is not limited thereto. Accordingly, the display device 100 according to an exemplary aspect of the present disclosure may be a non-rectangular heteromorphic display device. However, the type of the display device 100 according to an exemplary aspect of the present disclosure is not limited thereto.

The display area AA is disposed in a central area of the substrate 110 and may refer to an area where an image is displayed in the display device 100. A display element and various driving elements for driving the display element may be disposed in the display area AA. For example, the display element may include at least one light emitting element, and the driving elements may include a transistor, a capacitor and a line for driving the display element, but is not limited thereto.

The non-display area NA may be disposed in a peripheral area of the substrate 110. The non-display area NA may be disposed to surround the display area AA. The non-display area NA may refer to an area where an image is not displayed. Various components for driving a plurality of sub-pixels disposed in the display area AA may be disposed in the non-display area NA. For example, a driver IC, a driving circuit, a signal line, a flexible film, etc. that supply signals for driving the plurality of sub-pixels may be disposed in the non-display area NA. Herein, the driver IC may include gate driver (or a gate driving circuit), a data driver (or a data driving circuit) and the like. The gate driver and the data driver may be implemented by thin film transistors (TFT).

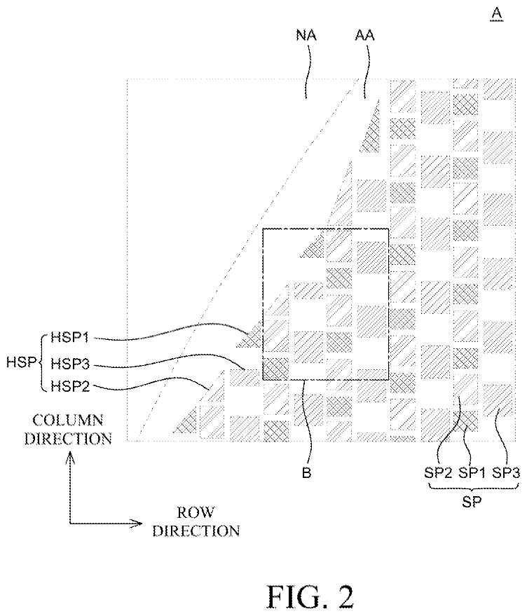

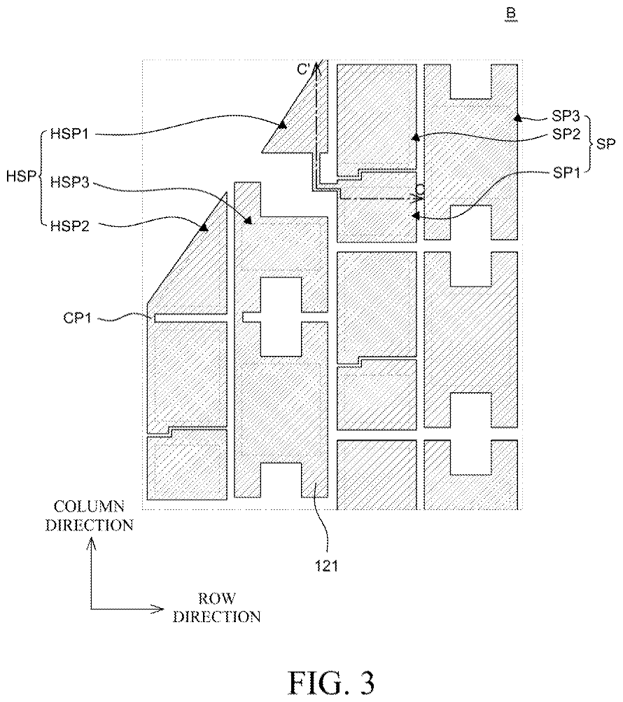

Hereinafter, the display device 100 will be described in more detail with reference to FIG. 2 and FIG. 3 together.

FIG. 2 is an enlarged plan view of an area A shown in FIG. 1. FIG. 3 is an enlarged plan view of an area B shown in FIG. 2. For the convenience of description, FIG. 2 illustrates only the display area AA, the non-display area NA, a plurality of sub-pixels SP and a plurality of heteromorphic sub-pixels HSP among various components of the display device 100. Also, for the convenience of description, FIG. 3 illustrates only the plurality of sub-pixels SP, the plurality of heteromorphic sub-pixels HSP, a connection part CP1 and an anode 121 among various components of the display device 100.

Referring to FIG. 2 and FIG. 3, the plurality of sub-pixels SP, the plurality of heteromorphic sub-pixels HSP and the connection part CP1 are disposed in the display area AA.

Each sub-pixel SP is a minimum unit constituting a screen and may include a light emitting element and a driving element. In this case, the driving element may include a switching transistor, a driving transistor and the like. The driving element may be electrically connected to signal lines, such as a gate line and a data line, which are connected to a gate driver and a data driver disposed in the non-display area NA, but is not limited thereto.

Each of the plurality of sub-pixels SP may include a first sub-pixel SP1, a second sub-pixel SP2 and a third sub-pixel SP3 that emit light of different colors. For example, the first sub-pixel SP1 may be a red sub-pixel, the second sub-pixel SP2 may be a green sub-pixel, and the third sub-pixel SP3 may be a blue sub-pixel. Each of the plurality of sub-pixels SP may further include a white sub-pixel, but is not limited thereto.

Referring to FIG. 2 and FIG. 3, each of the plurality of sub-pixels SP is disposed in a different row from other sub-pixels SP adjacent thereto in a row direction. Also, each of the plurality of sub-pixels SP is disposed in the same column as other sub-pixels SP adjacent thereto in a column direction. That is, the plurality of sub-pixels SP may be disposed to be misaligned in the row direction.

It has been described that the plurality of sub-pixels SP includes the first sub-pixel SP1, the second sub-pixel SP2 and the third sub-pixel SP3, and the plurality of sub-pixels SP is disposed to be misaligned in the row direction. However, the placement, the number and a color combination of the plurality of sub-pixels SP may vary depending on a design and are not limited thereto.

Each of the plurality of sub-pixels SP includes an emission area that emits light. Referring to FIG. 2 and FIG. 3, the emission area of each of the plurality of sub-pixels SP may have a polygonal shape when viewed from the top. For example, the emission area of each of the plurality of sub-pixels SP may have a rectangular shape when viewed from the top, but is not limited thereto.

Referring to FIG. 2 and FIG. 3, the first sub-pixel SP1, the second sub-pixel SP2 and the third sub-pixel SP3 may have a different size from one another. For example, in the display device 100 according to an exemplary aspect of the present disclosure, the first sub-pixel SP1, the second sub-pixel SP2 and the third sub-pixel SP3 emit light of different colors and have a different size from one another. Therefore, it is possible to control the color temperature and luminance ratio required for the display device 100. However, each of the plurality of sub-pixels SP may have the same size, but the present disclosure is not limited thereto.

The plurality of heteromorphic sub-pixels HSP is disposed in an outer portion of the display area AA corresponding to a curved area of the substrate 110. That is, the plurality of heteromorphic sub-pixels HSP may be disposed in the outermost portion of the display area AA while surrounding the plurality of sub-pixels SP. For example, each of the plurality of heteromorphic sub-pixels HSP may include the same light emitting element and the same driving element as the plurality of sub-pixels SP and may be formed by the same process as the plurality of sub-pixels SP.

Each of the plurality of heteromorphic sub-pixels HSP includes a first heteromorphic sub-pixel HSP1, a second heteromorphic sub-pixel HSP2 and a third heteromorphic sub-pixel HSP3 that emit light of different colors. Specifically, each of the plurality of heteromorphic sub-pixels HSP may include the first heteromorphic sub-pixel HSP1, the second heteromorphic sub-pixel HSP2 and the third heteromorphic sub-pixel HSP3 that emit light of the same color as the first sub-pixel SP1, the second sub-pixel SP2 and the third sub-pixel SP3, respectively.

For example, the first heteromorphic sub-pixel HSP1 may be a red sub-pixel, the second heteromorphic sub-pixel HSP2 may be a green sub-pixel, and the third heteromorphic sub-pixel HSP3 may be a blue sub-pixel. If each of the plurality of sub-pixels SP further includes a white sub-pixel, each of the plurality of heteromorphic sub-pixels HSP may also include a white sub-pixel, but is not limited thereto.

The plurality of heteromorphic sub-pixels HSP may be different in shape or size from the plurality of sub-pixels SP. Accordingly, the plurality of heteromorphic sub-pixels HSP may be configured to emit light in the same manner as the plurality of sub-pixels SP and may be different in only shape or size from the plurality of sub-pixels SP.

Each of the plurality of heteromorphic sub-pixels HSP includes an emission area that emits light. Referring to FIG. 2 and FIG. 3, the emission area of each of the plurality of heteromorphic sub-pixels HSP may have a polygonal shape when viewed from the top. For example, the emission area of each of the plurality of heteromorphic sub-pixels HSP may have a right triangular shape or a rectangular shape when viewed from the top, but is not limited thereto.

Meanwhile, referring to FIG. 3, the right triangular emission area of each of the heteromorphic sub-pixels HSP1 and HSP2 among the plurality of heteromorphic sub-pixels HSP may have the base and height respectively equal to those of the rectangular emission area of each of the sub-pixels SP1 and SP2. The heteromorphic sub-pixels HSP1 and HSP2 cmit light of the same color as the sub-pixels SP1 and SP2, respectively. Further, the rectangular emission area of the third heteromorphic sub-pixel HSP3 among the plurality of heteromorphic sub-pixels HSP may have the base equal to that of the rectangular emission area of the third sub-pixel SP3. Furthermore, the rectangular emission area of the third sub-pixel SP3 may be twice the height of the rectangular emission area of the third heteromorphic sub-pixel HSP3.

That is, each of the plurality of heteromorphic sub-pixels HSP may be smaller in size than a sub-pixel SP that emits light of the same color. Each of the plurality of heteromorphic sub-pixels HSP may be half the size of the sub-pixel SP that emits light of the same color. Accordingly, an area ratio of the first sub-pixel SP1, the second sub-pixel SP2 and the third sub-pixel SP3 may be equal to that of the first heteromorphic sub-pixel HSP1, the second heteromorphic sub-pixel HSP2 and the third heteromorphic sub-pixel HSP3. Therefore, the plurality of heteromorphic sub-pixels HSP different in shape or size from the plurality of sub-pixels SP may be configured to have same color temperature and luminance ratio as the plurality of sub-pixels SP. Thus, it is possible to minimize changes in color temperature and luminance ratio of the display device 100 caused by the plurality of heteromorphic sub-pixels HSP, but the present disclosure is not limited thereto.

Referring to FIG. 3, the connection part CP1 is disposed between the plurality of sub-pixels SP and the plurality of heteromorphic sub-pixels HSP. The connection part CP1 is electrically connected to the plurality of sub-pixels SP and the plurality of heteromorphic sub-pixels HSP. Specifically, each of the plurality of heteromorphic sub-pixels HSP is connected to any one of the plurality of sub-pixels SP by the connection part CP1.

The connection part CP1 electrically connects a heteromorphic sub-pixel HSP and a sub-pixel SP that emit light of the same color. That is, the heteromorphic sub-pixel HSP and the sub-pixel SP connected by the connection part CP1 emit light of the same color. Accordingly, each of the plurality of heteromorphic sub-pixels HSP may be configured to emit light together with a sub-pixel SP electrically connected thereto.

In this case, the connection part CP1 may be disposed on the same layer and made of the same material as the anode 121 of the light emitting element included in the plurality of sub-pixels SP. That is, the light emitting element included in the sub-pixel SP and the light emitting element included in the heteromorphic sub-pixel HSP may share the same anode 121 and may be electrically connected to each other. Also, the connection part CP1 may be a part extending from the anode 121 between the sub-pixel SP and the heteromorphic sub-pixel HSP.

Meanwhile, referring to FIG. 2 and FIG. 3, the second heteromorphic sub-pixel HSP2 and the third heteromorphic sub-pixel HSP3 are disposed in the same column as the second sub-pixel SP2 and the third sub-pixel SP3. Also, the first heteromorphic sub-pixel HSP1 is disposed in a different column from the first sub-pixel SP1. Thus, each of the first heteromorphic sub-pixel HSP1, the second heteromorphic sub-pixel HSP2 and the third heteromorphic sub-pixel HSP3 may be disposed adjacent to the first sub-pixel SP1, the second sub-pixel SP2 and the third sub-pixel SP3. Therefore, it is possible to minimize the area where the connection part CP1 is disposed to connect the plurality of sub-pixels SP to the plurality of heteromorphic sub-pixels HSP. Also, it is possible to optimize the placement of the plurality of sub-pixels SP and the plurality of heteromorphic sub-pixels HSP.

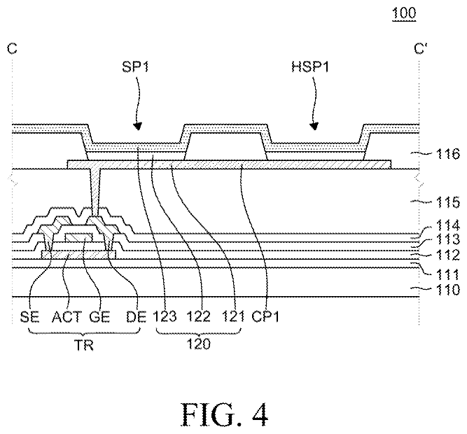

Hereinafter, the display device 100 will be described in more detail with reference to FIG. 4 together.

FIG. 4 is a cross-sectional view as taken along a line C-C′ of FIG. 3. For the convenience of description, FIG. 4 illustrates only the sub-pixel SP, the heteromorphic sub-pixel HSP, the substrate 110, a buffer layer 111, a gate insulating layer 112, an interlayer insulating layer 113, a passivation layer 114, a planarization layer 115, a bank 116, a light emitting element 120 and a connection part CP among various components of the display device 100.

Referring to FIG. 4, the display device 100 according to an exemplary aspect of the present disclosure includes the plurality of sub-pixels SP, the plurality of heteromorphic sub-pixels HSP, the substrate 110 and the buffer layer 111. Also, the display device 100 includes the gate insulating layer 112, the interlayer insulating layer 113, the passivation layer 114, the planarization layer 115, the bank 116, the light emitting element 120 and the connection part CP.

Each of the plurality of sub-pixels SP is an individual unit that emits light. In each of the plurality of sub-pixels SP, a transistor TR and the light emitting element 120 are disposed. The plurality of sub-pixels SP includes the first sub-pixel SP1, the second sub-pixel SP2 and the third sub-pixel SP3 that emit light of different colors. For example, the first sub-pixel SP1 may be a blue sub-pixel, the second sub-pixel SP2 may be a green sub-pixel and the third sub-pixel SP3 may be a red sub-pixel, but the present disclosure is not limited thereto.

The plurality of heteromorphic sub-pixels HSP may be configured to emit light in the same manner as the plurality of sub-pixels SP and may be different in only shape or size from the plurality of sub-pixels SP. In each of the plurality of heteromorphic sub-pixels HSP, the transistor TR and the light emitting element 120 are disposed. The plurality of heteromorphic sub-pixels HSP includes the first heteromorphic sub-pixel HSP1, the second heteromorphic sub-pixel HSP2 and the third heteromorphic sub-pixel HSP3 that emit light of different colors. For example, the first heteromorphic sub-pixel HSP1 may be a red sub-pixel, the second heteromorphic sub-pixel HSP2 may be a green sub-pixel and the third heteromorphic sub-pixel HSP3 may be a blue sub-pixel, but the present disclosure is not limited thereto.

The substrate 110 is a component for supporting the other components of the display device 100 and may be made of an insulating material. For example, the substrate 110 may be made of glass or resin. Also, the substrate 110 may contain a polymer or plastic such as polyimide (PI) and may be made of a material having flexibility.

The buffer layer 111 is disposed on the substrate 110. The buffer layer 111 may reduce permeation of moisture or impurities through the substrate 110. For example, the buffer layer 111 may be configured by a single layer or a plurality of layers of silicon oxide (SiOx) or silicon nitride (SiNx), but is not limited thereto. However, the buffer layer 111 may be omitted depending on the type of substrate 110 or the type of the transistor, but is not limited thereto.

The transistor TR is disposed on the buffer layer 111. The transistor TR includes an active layer ACT, a gate electrode GE, a source electrode SE and a drain electrode DE.

The active layer ACT may be made of a semiconductor material such as an oxide semiconductor, amorphous silicon or polysilicon, but is not limited thereto. For example, when the active layer ACT is made of an oxide semiconductor, the active layer ACT is composed of a channel region, a source region and a drain region. Herein, the source region and the drain region may be conductive regions, but are not limited thereto.

The gate insulating layer 112 is disposed on the active layer ACT. The gate insulating layer 112 serves as an insulating layer to insulate the active layer ACT from the gate electrode GE. The gate insulating layer 112 may be configured by a single layer or a plurality of layers of silicon oxide (SiOx) or silicon nitride (SiNx), but is not limited thereto.

The gate electrode GE is disposed on the gate insulating layer 112. The gate electrode GE may be made of a conductive material such as copper (Cu), aluminum (Al), molybdenum (Mo), nickel (Ni), titanium (Ti), chromium (Cr) or an alloy thereof, but is not limited thereto.

The interlayer insulating layer 113 is disposed on the gate electrode GE. In the interlayer insulating layer 113, contact holes for connecting the source electrode SE and the drain electrode DE to the active layer ACT are formed. The interlayer insulating layer 113 may be configured by a single layer or a plurality of layers of silicon oxide (SiOx) or silicon nitride (SiNx), but is not limited thereto.

The source electrode SE and the drain electrode DE are disposed on the interlayer insulating layer 113. The source electrode SE and the drain electrode DE which are disposed to be spaced apart from each other may be electrically connected to the active layer ACT. The source electrode SE and the drain electrode DE may be made of a conductive material such as copper (Cu), aluminum (Al), molybdenum (Mo), nickel (Ni), titanium (Ti), chromium (Cr) or an alloy thereof, but is not limited thereto.

The passivation layer 114 is disposed on the source electrode SE and the drain electrode DE. The passivation layer 114 is an insulating layer for protecting components below the passivation layer 114. For example, the passivation layer 114 may be configured by a single layer or a plurality of layers of silicon oxide (SiOx) or silicon nitride (SiNx), but is not limited thereto. Further, the passivation layer 114 may be omitted depending on an exemplary aspect.

The planarization layer 115 is disposed on the passivation layer 114. The planarization layer 115 is an insulating layer which planarizes an upper portion of the substrate 110. The planarization layer 115 may be made of an organic material and may be configured by a single layer or a plurality of layers of, for example, polyimide or photo acryl, but is not limited thereto.

A plurality of light emitting elements 120 is disposed respectively in the plurality of sub-pixels SP and the plurality of heteromorphic sub-pixels HSP on the planarization layer 115. The light emitting element 120 includes the anode 121, an organic layer 122 and a cathode 123.

The anode 121 is disposed on the planarization layer 115 in the display area AA. The anode 121 is electrically connected to the transistor TR of a pixel circuit and may be supplied with a driving current. The anode 121 supplies holes to the organic layer 122 and thus may be made of a conductive material having a high work function. For example, the anode 121 may be made of a transparent conductive material such as indium tin oxide (ITO) and indium zinc oxide (IZO), but is not limited thereto.

Referring to FIG. 4, the connection part CP is disposed between the sub-pixel SP and the heteromorphic sub-pixel HSP. Specifically, the connection part CP1 may be a part extending from the anode 121 between the sub-pixel SP and the heteromorphic sub-pixel HSP. The sub-pixel SP and the heteromorphic sub-pixel HSP electrically connected by the connection part CP may share the anode 121. Accordingly, the sub-pixel SP and the heteromorphic sub-pixel HSP connected by the connection part CP may be electrically connected to the same transistor TR.

Meanwhile, the display device 100 may be implemented by a top emission type or a bottom emission type. When the display device 100 is of a top emission type, a reflective layer made of a metal material having an excellent reflection efficiency such as aluminum (Al) or silver (Ag) may be added below the anode 121. Therefore, light emitted from the organic layer 122 is reflected from the anode 121 to be directed upwards, that is, toward the cathode 123. In contrast, when the display device 100 is of a bottom emission type, the anode 121 may be made of only a transparent conductive material. Hereinafter, the description will be made under the assumption that the display device 100 according to an exemplary aspect of the present disclosure is of a top emission type.

The bank 116 is disposed on the anode 121 and the planarization layer 115. The bank 116 is an insulating layer disposed between the plurality of sub-pixels SP and the plurality of heteromorphic sub-pixels HSP to divide the plurality of sub-pixels SP and the plurality of heteromorphic sub-pixels HSP. The bank 116 includes an opening which exposes a part of the anode 121. The bank 116 may be an organic insulating material disposed to cover an edge or a border of the anode 121. For example, the bank 116 may be made of polyimide, acryl or benzocyclobutene (BCB)-based resin, but is not limited thereto.

The organic layer 122 is disposed on the anode 121 and the bank 116. The organic layer 122 includes an emission layer. The emission layer is an organic layer for emitting light of a specific color. Thus, different emission layers may be disposed on the first sub-pixel SP1, the second sub-pixel SP2 and the third sub-pixel SP3, respectively, or the same emission layer may be disposed on all the plurality of sub-pixels SP. For example, when different emission layers are disposed on the plurality of sub-pixels SP, respectively, a blue emission layer may be disposed in the first sub-pixel SP1, a green emission layer may be disposed in the second sub-pixel SP2, and a red emission layer may be disposed in the third sub-pixel SP3. Further, the emission layers of the plurality of sub-pixels SP are connected to each other to be formed as one layer over the plurality of sub-pixels SP. For example, the emission layer may be disposed on all the plurality of sub-pixels SP and light from the emission layer may be converted into light of various colors by means of separate light converting layers, color filters, or the like.

Alternatively, a plurality of emission layers that emits light of the same color may be laminated on one sub-pixel SP. For example, two blue emission layers may be laminated on the first sub-pixel SP1, two green emission layers may be laminated on the second sub-pixel SP2, and two red emission layers may be laminated on the third sub-pixel SP3. In this case, a charge generation layer CGL may be disposed between the plurality of emission layers to smoothly supply electrons or holes to each of the plurality of emission layers. That is, the charge generation layer may be disposed between the two blue emission layers, between the two green emission layers and between the two red emission layers.

Otherwise, a plurality of emission layers that emits light of different colors may be laminated on one sub-pixel SP. For example, a blue emission layer and a yellow-green emission layer may be laminated on all the plurality of sub-pixels SP, and, thus, all the plurality of sub-pixels SP may implement white light. In this case, the charge generation layer may be disposed between the blue emission layer and the yellow-green emission layer.

Meanwhile, although not illustrated in FIG. 4, a common layer may be further included in the organic layer to improve an emission efficiency of the emission layer. For example, the common layer may be formed as one layer over the plurality of sub-pixels SP. That is, the common layers of the plurality of sub-pixels SP may be connected to each other to be integrally formed. The common layer may include a charge generation layer, a hole injection layer, a hole transport layer, an electron transport layer, an electron injection layer, or the like, but is not limited thereto.

The cathode 123 is disposed on the organic layer 122. The cathode 123 supplies electrons to the organic layer 122 and thus may be made of a conductive material having a low work function. The cathode 123 may be formed as one layer over the plurality of sub-pixels SP. That is, the cathodes 123 of the plurality of sub-pixels SP may be connected to each other to be integrally formed.

For example, the cathode 123 may be made of a transparent conductive material such as indium tin oxide (ITO) or indium zinc oxide (IZO), or a metal alloy such as MgAg and ytterbium (Yb) alloy. Also, the cathode 123 may further include a metal doping layer, but is not limited thereto.

Meanwhile, although not illustrated in FIG. 4, an encapsulation layer disposed on the light emitting element 120 may be further included in the display device 100. The encapsulation layer may protect the light emitting element 120 against moisture permeating from the outside of the display device 100. The encapsulation layer may be a single layer or may be composed of a plurality of layers including, for example, a first inorganic encapsulation layer, an organic encapsulation layer and a second inorganic encapsulation layer, but is not limited thereto.

In the display device 100 according to an exemplary aspect of the present disclosure, the heteromorphic sub-pixel HSP is disposed in the outermost portion of the display area AA. Therefore, the aesthetics of the curved area may be improved.

Specifically, a plurality of sub-pixels of the display device has a regular shape such as a rectangular shape. Thus, a plurality of sub-pixels disposed in the curved area may have a step difference in the outer portion of the plurality of sub-pixels. Therefore, when a user perceives such a step difference, the user may have a sense of difference and the display quality of the display device may be degraded. Particularly, such a perceivable difference in step may be more noticeable on a display device with larger sized sub-pixels and lower resolution.

Accordingly, in the display device 100 according to an exemplary aspect of the present disclosure, the plurality of heteromorphic sub-pixels HSP is disposed in the outermost portion of the display area AA while surrounding the plurality of sub-pixels SP. The plurality of heteromorphic sub-pixels HSP may be configured to emit light in the same manner as the plurality of sub-pixels SP and may be different in only shape or size from the plurality of sub-pixels SP. The plurality of heteromorphic sub-pixels HSP is disposed at a step portion formed by the plurality of sub-pixels SP in the outermost portion of the display area AA. Further, the plurality of heteromorphic sub-pixels HSP is different in shape or size from the plurality of sub-pixels SP and thus may compensate for a step difference between the plurality of sub-pixels SP disposed in a regular shape. Accordingly, the plurality of heteromorphic sub-pixels HSP may improve a step difference between the plurality of sub-pixels SP to be curved similar to the curved area. Therefore, in the display device 100 according to an exemplary aspect of the present disclosure, the plurality of heteromorphic sub-pixels HSP is disposed in the outermost portion of the display area AA and improves a step difference between the plurality of sub-pixels SP. Therefore, the aesthetics of the curved area may be improved and the display quality of the display device 100 may be enhanced.

In the display device 100 according to an exemplary aspect of the present disclosure, the emission area of each of the plurality of heteromorphic sub-pixels HSP is configured to have a polygonal shape when viewed from the top. Therefore, the manufacturing process of the display device 100 may be simplified.

Specifically, a plurality of heteromorphic sub-pixels is disposed to improve a step difference between a plurality of sub-pixels in an outer portion of a display area corresponding to a curved area of a display device. In this case, the plurality of heteromorphic sub-pixels needs to be formed to have different shaped curves, respectively, to be entirely identical in shape to the curved area. Accordingly, a complicated manufacturing process for forming a plurality of heteromorphic sub-pixels having different shaped curves, respectively, may be necessary. Also, it may be difficult to produce a mask for forming a plurality of heteromorphic sub-pixels having different shaped curves, respectively.

Accordingly, in the display device 100 according to an exemplary aspect of the present disclosure, the emission area of each of the plurality of heteromorphic sub-pixels HSP is configured to have a polygonal shape when viewed from the top. Also, the plurality of heteromorphic sub-pixels HSP each having a polygonal shape is disposed at a step portion formed by the plurality of sub-pixels SP. Therefore, the plurality of heteromorphic sub-pixels HSP is disposed similar in shape to the curved area and thus may improve a step difference between the plurality of sub-pixels SP. Further, each of the plurality of heteromorphic sub-pixels HSP is disposed having a polygonal shape. Thus, a process of manufacturing the plurality of heteromorphic sub-pixels HSP to have curves with different curvatures may be omitted. Therefore, the manufacturing process of the display device 100 may be simplified. Accordingly, in the display device 100 according to an exemplary aspect of the present disclosure, the emission area of each of the plurality of heteromorphic sub-pixels HSP is configured to have a polygonal shape when viewed from the top. Thus, the manufacturing process of the display device 100 may be simplified and the production energy for the display device 100 may be reduced. Therefore, it is possible to provide a process-optimized display device.

Meanwhile, referring back to FIG. 2, in the display device 100 according to an exemplary aspect of the present disclosure, the plurality of heteromorphic sub-pixels HSP may be disposed in different sizes according to the curvature of the curved area. For example, each of the plurality of heteromorphic sub-pixels HSP may have a greater size at a portion where a step difference caused by a curvature difference in the curved area is greater than the size of two sub-pixels SP than at a portion where the step difference is smaller. Accordingly, in the display device 100 according to an exemplary aspect of the present disclosure, it is possible to further improve a step difference between the plurality of sub-pixels SP. Also, it is possible to further improve the aesthetics of the curved area.

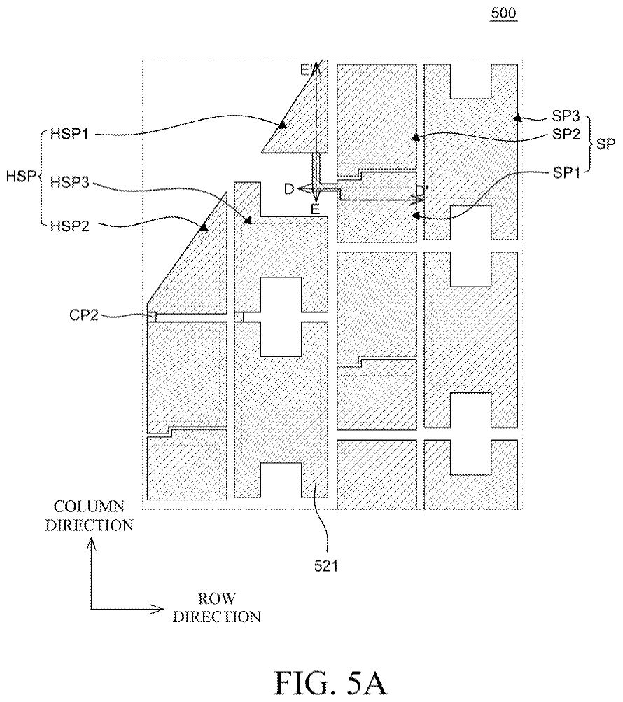

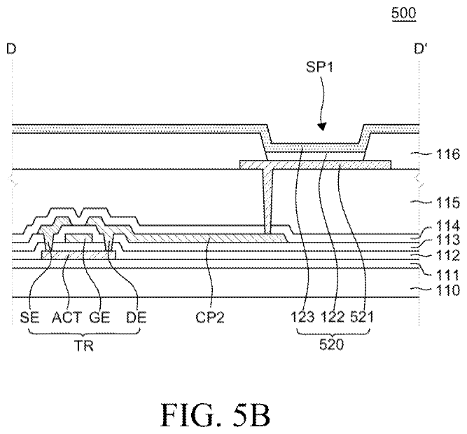

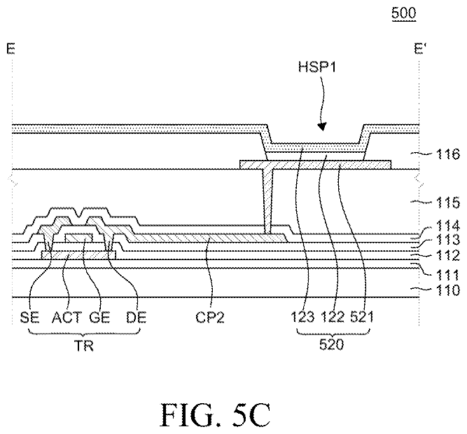

Hereinafter, a display device 500 according to another exemplary aspect of the present disclosure will be described with reference to FIG. 5A through FIG. 5C.

FIG. 5A is an enlarged plan view of a display device according to another exemplary aspect of the present disclosure. FIG. 5B is a cross-sectional view as taken along a line D-D′ of FIG. 5A. FIG. 5C is a cross-sectional view as taken along a line E-E′ of FIG. 5A. The display device 500 illustrated in FIG. 5A through FIG. 5C is substantially the same as the display device 100 illustrated in FIG. 1 through FIG. 4 except a connection part CP2. Therefore, a redundant description will be omitted.

Referring to FIG. 5A through FIG. 5C, the connection part CP2 is disposed on the same layer and made of the same material as the source electrode SE and the drain electrode DE. For example, the connection part CP2 may be a part extending from the drain electrode DE. However, in the present disclosure, the connection part CP2 is described as a part extending from the drain electrode DE for the convenience of description. However, the connection part CP2 may be made of the same material as another component of the transistor TR, but is not limited thereto.

The sub-pixel SP and the heteromorphic sub-pixel HSP connected by the connection part CP2 may be electrically connected to the same transistor TR. That is, an anode 521 is individually disposed in a light emitting element 520 of each of the sub-pixel SP and the heteromorphic sub-pixel HSP, and the sub-pixel SP and the heteromorphic sub-pixel HSP connected by the connection part CP2 may share the same transistor TR. Specifically, referring to FIG. 5B and FIG. 5C, each of the sub-pixel SP and the heteromorphic sub-pixel HSP may be electrically connected to the connection part CP2, which is a part extending from the drain electrode DE, through a contact hole formed in the planarization layer 115.

In the display device 500 according to another exemplary aspect of the present disclosure, the sub-pixel SP and the heteromorphic sub-pixel HSP connected by the connection part CP2 are configured to share the same transistor TR. Thus, a defect in the outermost portion of a display area AA may be easily repaired.

Specifically, in the display device, a dark spot defect is highly likely to occur in the outermost portion of the display area AA. Such a dark spot defect may be caused by a foreign substance or a defect of a light emitting element or driving element included in a sub-pixel. A dark spot defect caused by a foreign substance may be repaired by irradiating a laser beam to a sub-pixel where the foreign substance is detected during a lighting test and removing the foreign substance. However, a dark spot defect caused by a defect of a light emitting element or driving element included in a sub-pixel may require a complicated repair process because the light emitting element or driving element included in the sub-pixel needs to be replaced.

Accordingly, in the display device 500 according to another exemplary aspect of the present disclosure, the sub-pixel SP and the heteromorphic sub-pixel HSP disposed in the outermost portion of the display area AA are electrically connected by the connection part CP2. Also, the sub-pixel SP and the heteromorphic sub-pixel HSP disposed in the outermost portion of the display area AA are configured to share the same transistor TR. For example, a dark spot defect may occur due to a defect of the light emitting element 120 or the driving element included in the sub-pixel SP disposed in the outermost portion of the display area AA. In this case, the connection part CP2 connecting the sub-pixel SP including the defective light emitting element or defective driving element to the transistor TR is shorted in order for the heteromorphic sub-pixel HSP sharing the same transistor TR to normally emit light. Thus, the dark spot defect may be repaired. Therefore, a complicated process for repairing the dark spot defect caused by the defect of the light emitting element 120 or the driving element included in the sub-pixel SP disposed in the outermost portion of the display area AA may be omitted. Accordingly, the dark spot defect may be easily repaired. Meanwhile, the connection part CP2 may be shorted by, for example, laser irradiation, but is not limited thereto. In the display device 500 according to another exemplary aspect of the present disclosure, the sub-pixel SP and the heteromorphic sub-pixel HSP connected by the connection part CP2 are configured to share the same transistor TR. Thus, a complicated process for repairing a dark spot defect may be omitted. Therefore, it is possible to provide a process-optimized display device in which a defect occurring in the outermost portion of the display area AA may be easily repaired and which requires less production energy.

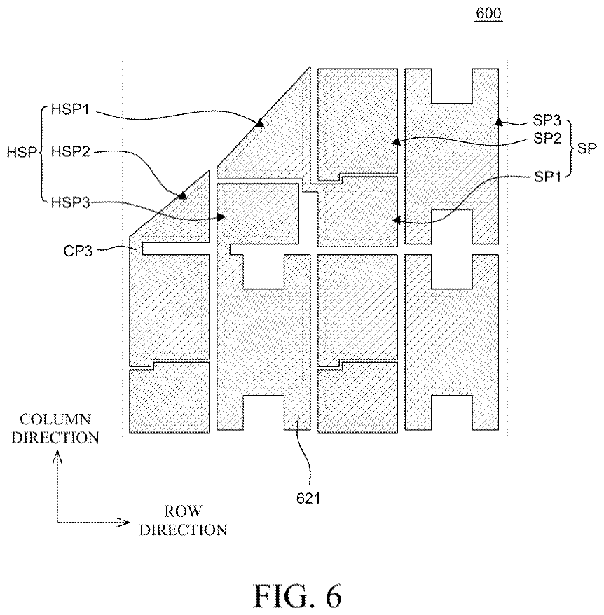

Hereinafter, a display device 600 according to yet another exemplary aspect of the present disclosure will be described with reference to FIG. 6.

FIG. 6 is an enlarged plan view of a display device according to yet another exemplary aspect of the present disclosure. The display device 600 illustrated in FIG. 6 is substantially the same as the display device 100 illustrated in FIG. 1 through FIG. 4 except the placement of the plurality of sub-pixels SP and the plurality of heteromorphic sub-pixels HSP. Therefore, a redundant description will be omitted.

Referring to FIG. 6, each of the plurality of sub-pixels SP is disposed in the same row as other sub-pixels SP adjacent thereto in a row direction. Also, each of the plurality of sub-pixels SP is disposed in the same column as other sub-pixels SP adjacent thereto in a column direction. That is, the plurality of sub-pixels SP in the display area AA may be regularly aligned both in the row direction and in the column direction.

Meanwhile, each of the plurality of heteromorphic sub-pixels HSP may be smaller in size than a sub-pixel SP that emits light of the same color, but is not limited thereto.

Referring to FIG. 6, a light emitting element 620 included in the sub-pixel SP and a light emitting element 620 included in the heteromorphic sub-pixel HSP may share an anode 621 and may be electrically connected to each other. Also, a connection part CP3 may be a part extending from the anode 621 between the sub-pixel SP and the heteromorphic sub-pixel HSP.

In the display device 600 according to yet another exemplary aspect of the present disclosure, the plurality of sub-pixels SP in the display area AA may be regularly aligned both in the row direction and in the column direction. Accordingly, a step difference between the plurality of sub-pixels SP may be regularly formed to have a size n times greater than a sub-pixel SP. Therefore, even if the plurality of heteromorphic sub-pixels HSP disposed to improve a step difference is formed in various shapes and sizes, the placement of the plurality of heteromorphic sub-pixels HSP may be regularly applied to each of regularly formed step portions. Thus, limitations in designing the shapes and sizes of the plurality of heteromorphic sub-pixels HSP may be reduced. Also, the plurality of heteromorphic sub-pixels HSP may have shapes and sizes to be curved similar to the curvature of a curved area. Therefore, the aesthetics of the curved area may be further improved.

The exemplary aspects of the present disclosure may also be described as follows:

According to an aspect of the present disclosure, the display device includes a substrate that has a display area in which a plurality of sub-pixels is disposed, a non-display area surrounding the display area, and at least one curved area. Also, the display device includes a plurality of heteromorphic sub-pixels disposed in an outer portion of the display area corresponding to the curved area. Further, the display device includes a connection part that electrically connects the plurality of sub-pixels and the plurality of heteromorphic sub-pixels. Each of the heteromorphic sub-pixels is connected to any one of the plurality of sub-pixels by the connection part.

The sub-pixel and the heteromorphic sub-pixel may connect by the connection part emit light of the same color.

Each of the plurality of sub-pixels and the plurality of heteromorphic sub-pixels may include an emission area that emits light.

The emission area of each of the heteromorphic sub-pixels may have a polygonal shape when viewed from the top.

The emission area of each of the plurality of sub-pixels may have a rectangular shape when viewed from the top.

The emission area of each of the plurality of heteromorphic sub-pixels may have a right triangular shape when viewed from the top.

The right triangular emission area of each of the heteromorphic sub-pixels may have the base and height respectively equal to those of the rectangular emission area of each of the sub-pixels that emit light of the same color as the heteromorphic sub-pixels.

The plurality of sub-pixels may include a first sub-pixel, a second sub-pixel and a third sub-pixel that emit light of different colors.

The plurality of heteromorphic sub-pixels may include a first heteromorphic sub-pixel, a second heteromorphic sub-pixel and a third heteromorphic sub-pixel that emit light of the same color as the first sub-pixel, the second sub-pixel and the third sub-pixel, respectively.

The emission area of each of the plurality of sub-pixels and the emission area of the third heteromorphic sub-pixel may have a rectangular shape when viewed from the top.

The rectangular emission area of the third heteromorphic sub-pixel may have the base equal to that of the rectangular emission area of the third sub-pixel.

The rectangular emission area of the third sub-pixel may be twice the height of the rectangular emission area of the third heteromorphic sub-pixel.

Each of the plurality of heteromorphic sub-pixels may be smaller in size than a sub-pixel that emits light of the same color.

Each of the plurality of sub-pixels may include a transistor including an active layer, a gate electrode, a source electrode and a drain electrode.

The sub-pixel and the heteromorphic sub-pixel may connect by the connection part are electrically connected to the same transistor.

Each of the plurality of sub-pixels and the plurality of heteromorphic sub-pixels may include an anode, an organic layer disposed on the anode and a cathode disposed on the organic layer.

The connection part may be disposed on the same layer and made of the same material as the anode.

The connection part may be disposed on the same layer and made of the same material as the source electrode and the drain electrode.

Each of the plurality of sub-pixels may be disposed in a different row from other sub-pixels adjacent thereto in a row direction and disposed in the same column as other sub-pixels adjacent thereto in a column direction.

The plurality of sub-pixels may include a first sub-pixel, a second sub-pixel and a third sub-pixel that emit light of different colors.

The plurality of heteromorphic sub-pixels includes a first heteromorphic sub-pixel, a second heteromorphic sub-pixel and a third heteromorphic sub-pixel that emit light of the same color as the first sub-pixel, the second sub-pixel and the third sub-pixel, respectively.

The second heteromorphic sub-pixel and the third heteromorphic sub-pixel may be disposed in the same column as the second sub-pixel and the third sub-pixel.

The first heteromorphic sub-pixel may be disposed in a different column from the first sub-pixel.

Each of the plurality of sub-pixels may be disposed in the same row as other sub-pixels adjacent thereto in a row direction and disposed in the same column as other sub-pixels adjacent thereto in a column direction.

Each of the plurality of heteromorphic sub-pixels may be smaller in size than a sub-pixel that emits light of the same color.

The plurality of sub-pixels may include a first sub-pixel, a second sub-pixel and a third sub-pixel that emit light of different colors.

The first sub-pixel, the second sub-pixel and the third sub-pixel may have a different size from one another.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate having a display area in which a plurality of sub-pixels is disposed, a non-display area surrounding the display area, and at least one curved area;
a plurality of heteromorphic sub-pixels disposed in an outer portion of the display area corresponding to the curved area; and
a connection part electrically connecting the plurality of sub-pixels and the plurality of heteromorphic sub-pixels,
wherein each of the heteromorphic sub-pixels is connected to one of the plurality of sub-pixels by the connection part.

2. The display device according to claim 1, wherein the sub-pixel and the heteromorphic sub-pixel connected by the connection part emit light of a same color.

3. The display device according to claim 1, wherein each of the plurality of sub-pixels and the plurality of heteromorphic sub-pixels includes an emission area that emits light, and
wherein the emission area of each of the heteromorphic sub-pixels has a polygonal shape in a plan view.

4. The display device according to claim 3, wherein the emission area of each of the plurality of sub-pixels has a rectangular shape in a plan view,
the emission area of each of the plurality of heteromorphic sub-pixels has a right triangular shape in a plan view, and
the right triangular emission area of each of the heteromorphic sub-pixels has a base and a height respectively equal to those of the rectangular emission area of each of the sub-pixels that emit light of a same color as the heteromorphic sub-pixels.

5. The display device according to claim 3, wherein the plurality of sub-pixels includes a first sub-pixel, a second sub-pixel and a third sub-pixel that emit light with different colors,
the plurality of heteromorphic sub-pixels includes a first heteromorphic sub-pixel, a second heteromorphic sub-pixel and a third heteromorphic sub-pixel that emit light of a same color as the first sub-pixel, the second sub-pixel and the third sub-pixel, respectively,
the emission area of each of the plurality of sub-pixels and the emission area of the third heteromorphic sub-pixel have a rectangular shape in a plan view,
the rectangular emission area of the third heteromorphic sub-pixel has a base equal to that of the rectangular emission area of the third sub-pixel, and
the rectangular emission area of the third sub-pixel is twice a height of the rectangular emission area of the third heteromorphic sub-pixel.

6. The display device according to claim 3, wherein each of the plurality of heteromorphic sub-pixels has a size smaller than a sub-pixel that emits light with a same color.

7. The display device according to claim 1, wherein each of the plurality of sub-pixels includes a transistor including an active layer, a gate electrode, a source electrode and a drain electrode, and
wherein the sub-pixel and the heteromorphic sub-pixel connected by the connection part are electrically connected to a same transistor.

8. The display device according to claim 7, wherein each of the plurality of sub-pixels and the plurality of heteromorphic sub-pixels includes an anode, an organic layer disposed on the anode and a cathode disposed on the organic layer, and
wherein the connection part is disposed on a same layer and made of a same material as the anode.

9. The display device according to claim 7, wherein the connection part is disposed on the same layer and made of a same material as the source electrode and the drain electrode.

10. The display device according to claim 1, wherein each of the plurality of sub-pixels is disposed in a different row from other sub-pixels adjacent thereto in a row direction and disposed in a same column as other sub-pixels adjacent thereto in a column direction.

11. The display device according to claim 10, wherein the plurality of sub-pixels includes a first sub-pixel, a second sub-pixel and a third sub-pixel that emit light with different colors,
wherein the plurality of heteromorphic sub-pixels includes a first heteromorphic sub-pixel, a second heteromorphic sub-pixel and a third heteromorphic sub-pixel that emit light of a same color as the first sub-pixel, the second sub-pixel and the third sub-pixel, respectively, and
wherein the second heteromorphic sub-pixel and the third heteromorphic sub-pixel are disposed in a same column as the second sub-pixel and the third sub-pixel.

12. The display device according to claim 11, wherein the first heteromorphic sub-pixel is disposed in a different column from the first sub-pixel.

13. The display device according to claim 1, wherein each of the plurality of sub-pixels is disposed in a same row as other sub-pixels adjacent thereto in a row direction and disposed in a same column as other sub-pixels adjacent thereto in a column direction.

14. The display device according to claim 13, wherein each of the plurality of heteromorphic sub-pixels has a size smaller than a sub-pixel that emits light with a same color.

15. The display device according to claim 1, wherein the plurality of sub-pixels includes a first sub-pixel, a second sub-pixel and a third sub-pixel that emit light of different colors, and
wherein the first sub-pixel, the second sub-pixel and the third sub-pixel have a size different from one another.
